(19) United States
(12) Patent Application Publication
(10) Pub. No.: US 2004/0004431 A1
(43) Pub. Date: Jan. 8, 2004

(54) Organic EL panel and manufacturing method thereof

(76) Inventor: Ryuji Nishikawa, Gifu-shi (JP)

Correspondence Address: CANTOR COLBURN, LLP, 55 GRIFFIN ROAD SOUTH, BLOOMFIELD, CT, 06002

(21) Appl. No.: 10/422,324

(22) Filed: Apr. 24, 2003

(30) Foreign Application Priority Data
Apr. 26, 2002 (JP) 2002-126999

(51) Int. Cl. H05B 33/00

(52) U.S. Cl. 313/504

(57) ABSTRACT

A second planarization (insulating) film is formed so as to cover the periphery of a pixel electrode. Then, using the same mask, a hole transport layer, an organic emissive layer, and an electron transport layer are sequentially formed. In particular, use of larger anisotropy in evaporation for upper layers results in the upper layers which are smaller than the lower layers. Thus, the lateral side of the lower layer is not covered by the upper layer. This can reduce immixing of dust attributable to use of a mask.

### BACKGROUND OF THE INVENTION

1. Field of the Invention

The present invention relates to an organic EL panel having organic EL elements arranged in a matrix and a manufacturing method thereof.

2. Description of the Related Art

One type of conventionally known flat display panel is an organic EL display panel. Organic EL display panels are self-emissive, which is different from liquid crystal display panels (LCD), and are widely expected to come into wide use as bright and easy-to-view flat display panels.

An organic EL display includes, as pixels, a number of organic EL elements arranged in a matrix. An organic EL element has a structure in which a hole transport layer, an organic emissive layer, an electron transport layer, and a cathode made of aluminum or the like are stacked on an anode made of ITO or the like.

While an individual anode (a pixel electrode) is formed for every pixel to control display by each pixel, other layers may often be formed spreading over the entire surface of the substrate. However, for a highly precise panel, in which unnecessary light emission may highly likely be caused due to a short distance between adjacent pixels, an organic emissive layer also is generally formed for every pixel.

Here, an electron transport layer often contains light emissive material such as Alq₃, and thus is desirably patterned for every pixel. For similar reasons, patterning of an electron transport layer is also suggested. For the patterning, in order to effectively supply electrons to the entire organic emissive layer, an electron transport layer larger than the organic emissive layer is formed so as to fully cover the organic emissive layer.

Here, organic layers including an organic emissive layer and an electron transport layer are formed through vacuum evaporation. The mask employed during evaporation has an opening at a predetermined position at which an organic layer is to be deposited. In particular, because different masks must be used to attain different patterns for an organic emissive layer and an electron transport layer, masks are usually exchanged. The exchange requires an extra process of exchanging masks and, moreover, use of different masks may increase the risk of immixing dust as a mask may be a source of dust.

Attempts to employ the same mask in vacuum evaporation for an organic emissive layer and an electron transport layer have resulted in electron transport layers having thinner peripheral portions which cover the peripheral portions of an organic emissive layer as the edges of these layers are located at the substantially same position. This reduces electric resistance of the electron transport layer at that position, which increases an amount of current flowing therein and thus causes more intensive light emission from the electron transport layer. In other words, the attempts have resulted in reduction or deterioration in the capabilities of the panel.

### SUMMARY OF THE INVENTION

The present invention enables formation of an organic emissive layer and an electron transport layer using the same mask.

In the present invention, an electron transport layer to be formed on an organic emission layer is slightly smaller than the organic emission layer. This allows a single mask to be used for deposition of both of these layers, eliminating the need to exchange masks during the evaporation process. As a result, deposition efficiency can be improved and the likelihood of contamination from dust or the like can be reduced. Further, adverse effect on light emission due to coverage of the lateral sides of the lower layer by a thinner portion of the upper layer can be avoided when the upper layer is smaller than the lower layer.

### BRIEF DESCRIPTION OF THE DRAWINGS

FIG. 1 is a diagram showing a structure of a pixel portion in an embodiment of the present invention;

FIG. 2 is a diagram showing a structure of a pixel portion in another embodiment of the present invention;

FIGS. 3A and 3B are plan views schematically showing a structure of the pixel portion in the first embodiment of the present invention; and

FIGS. 4A and 4B are plan views schematically showing a structure of the pixel portion in the further embodiment of the present invention.

### DESCRIPTION OF THE PREFERRED EMBODIMENTS

In the following, the present invention will be described with reference to the drawings.

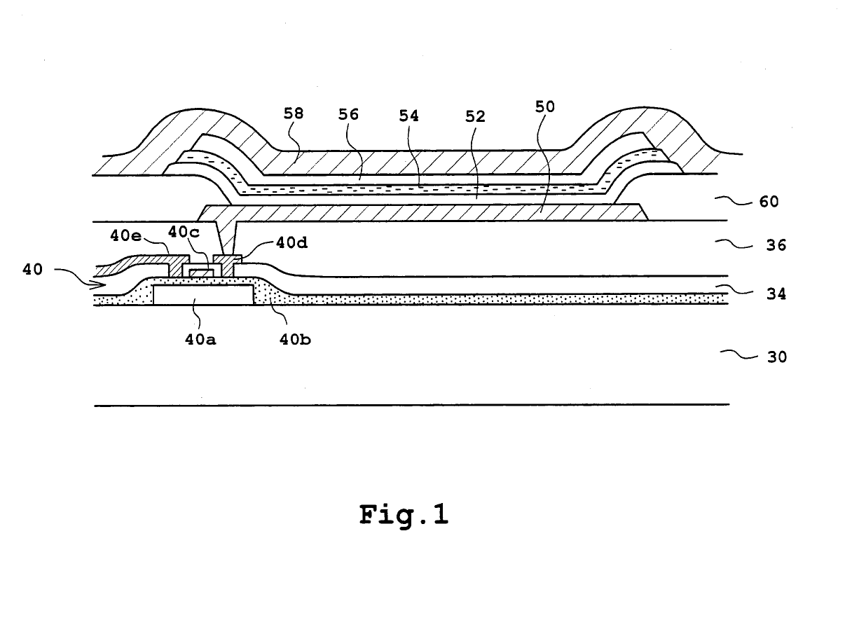

FIG. 1 shows an example pixel structure. Although the drawing illustrates only a driving TFT 40 and an organic EL element EL, on an active matrix element substrate are actually formed two TFTs, one capacitor, and one organic EL element EL for every pixel.

The illustrated element substrate comprises a driving TFT 40 formed on a glass substrate 30, and an organic EL element is connected to the driving TFT 40.

The driving TFT 40, formed on the glass substrate 30, includes an active layer 40a made of low temperature poly-silicon. Both ends of the active layer 40a are doped with impurities, constituting a source region and a drain region, respectively, and the center thereof constitutes a channel region. Lying above the channel region via a gate insulating film 40b made of silicon oxide is a gate electrode 40c. The gate insulating film 40b and the gate electrode 40c are covered by an inter-layer insulating film 34. On both sides of the gate electrode 40c are formed a source electrode 40d and a drain electrode 40e, which are connected through a contact hole to the source and drain regions, respectively. The top ends of the source electrode 40d and the drain electrode 40e are located on the surface of the inter-layered insulating film 34.

Lying on the surface of the inter-layered insulating film 34 is a metallic wire or the like which connects the drain electrode 40e and the power source line. Further, a first planarization film 36, serving as an insulator film, is formed covering the inter-layer insulating film 34.

On the top surface of the first planarization film 36, a pixel electrode 50 made of transparent electric conductive material such as ITO is formed with one end thereof connected to the source electrode 40d of the driving TFT 40 through a contact hole formed through the first planarization film 36. The pixel electrode 50 is patterned so as to correspond to a light emitting region of one pixel.

The pixel electrode 50 constitutes an anode of the organic EL element. Above the pixel electrode 50 a hole transport layer 52, an organic emissive layer 54, an electron transport layer 56 and a metal cathode 58 are arranged. On the first planarization film 36, a second planarization film 60 is formed, covering a peripheral and outer area of the pixel electrode 50.

The hole-transport layer 52, formed on the pixel electrode 50, has peripheral portions which cover, and terminate on, the peripheral portions of the second planarization film 60. The organic light emissive layer 54, formed on the hole-transport layer 52, is slightly smaller than the hole-transport layer 52 so that its peripheral portions terminate slightly further towards the center, away from the side edges of the hole-transport layer 52. Similarly, the electron transport layer 56, formed on the organic light emissive layer 54, is also slightly smaller than the organic light emissive layer 54 so that its peripheral portions also terminate slightly closer to the center relative to the side edges of the organic light emissive layer 54.

The cathode 58, made of aluminum or the like, is formed fully covering the entire surface of the electron transport layer 56. Specifically, the cathode 58 covers portions which are otherwise uncovered, or exposed, and lateral sides of the electron transport layer 56, the organic light emissive layer 54, and the hole-transport layer 52, as well as the entire surface of the electron transport layer 56 and, in a region without these organic layers, directly the second planarization film 60.

For an organic EL panel having the above-described pixel structure, a driving TFT 40 is initially formed on the glass substrate 30. It should be noted that, in general, a switching TFT to be provided for every pixel, and a TFT of a driver circuit are also formed in the identical manner for the driving TFT. Then, a first planarization film 36 with a flat surface is formed covering the entire surface of the substrate.

After subsequent formation of a contact hole that exposes a surface of a source electrode 40d in the first planarization film 36, ITO is sputtered to be deposited and then patterned by means of dry etching into a shape suitable for a light emitting region, i.e., rectangular.

Thereafter, a second planarization film 60, made of sensitizer-contained acrylic resin, is formed through vacuum evaporation on the entire surface of the formed films, and then patterned by means of photolithography, or light irradiation toward_either a necessary or unnecessary portion and subsequent etching. Through this processing, the second planarization film 60 is formed so as to cover the peripheral portions of the pixel electrode 50, leaving the central portion of the pixel electrode 50 exposed.

Then, a mask is placed so as to cover the second planarization film 60. With the mask so placed, the hole-transport layer 52, the organic light emissive layer 54, and the electron transport layer 56 are sequentially formed through vacuum evaporation.

In the vacuum evaporation, different evaporation sources, and thus materials, are used for the respective layers while anisotropy in a direction in which to direct the evaporation material toward the substrate via the mask is controlled. Specifically, the smallest anisotropy with large isotropic spread of the evaporation material_is employed in evaporation for the hole-transport layer 52, while the largest anisotropy with smaller spread is employed for the electron transport layer 56.

This control enables formation of the sequentially smaller hole-transport layer 52, organic light emissive layer 54, and electron transport layer 56, in that order. As a result, the edges of the organic light emissive layer 54 are terminated on the hole-transport layer 52, and the edges of the electron transport layer 56 are terminated on the organic light emissive layer 54, so that the lateral sides of the hole-transport layer 52 remain uncovered by the thinner portion of the organic light emissive layer 54, and the edges of the organic light emissive layer 54 remain uncovered by the thinner portion of the electron transport layer 56.

This can prevent current from flowing into the thinner portions of the organic light emissive layer 54 and the electron transport layer 56, and can thus preventively avoid factors which would reduce display quality, including reduced luminance at and around the central portion of a pixel and luminous spots formed along the peripheral portions of a pixel.

Further, because the respective layers are patterned for every pixel, undesired light emission due to an electric field effected from an adjacent pixel can be avoided.

The cathode 58 may preferably be formed having a relatively large thickness because a relatively large difference in height of the cathode 58 inevitably results at any point where the hole-transport layer 52, the organic light emissive layer 54, and the electron transport layer 56 terminate at substantially the same point.

It should be noted that the thickness of, for example, the second planarization film 60 is about 600 to 1300 nm; that of the hole-transport layer 52 is about 150 to 200 nm; that of the organic light emissive layer 54 is about 35 nm; that of the electron transport layer 56 is about 35 nm; and that of the pixel electrode 50 is about 300 to 400 nm.

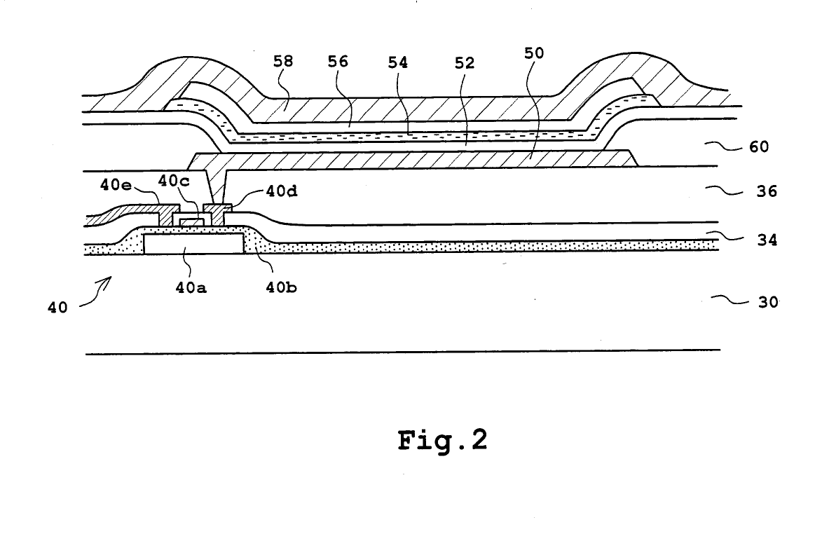

FIG. 2 shows another embodiment of the present invention, one in which the hole-transport layer 52 is formed spreading over the entire surface of the formed films, rather than patterned for every pixel. Generally, because the hole-transport layer 52 does not emit light, continuous formation of the hole-transport layer 52 so as to spread over the formed films is not problematic. Because no mask is required, continuous formation of the hole-transport layer 52 can in fact advantageously alleviate problems due to contamination from dust on a mask.

However, introduction of a mask after formation of the hole-transport layer 52 may increase the likelihood of dust contamination. Because the organic light emissive layer 54 and the electron transport layer 56, being thinner, are more susceptible to the affects of dust contamination than is the hole-transport layer 52, formation of these three layers by means of patterning appears more advantageous in terms of preventing dust contamination. However, elimination of patterning in formation of the hole-transport layer 52 can produce an additional advantage of eliminating adverse effects of height differences on the cathode 58, because a smaller difference in height of the cathode 58 is assured.

Here, anisotropic control in evaporation using a mask can be achieved using at least one of the following methods.

(i) The diameter of an ejection opening via which to eject evaporation material is reduced for larger anisotropy. For this purpose, an evaporation material reservoir having a smaller diameter opening is used in formation of the hole-transport layer 52, organic light emissive layer 54, and the electron transport layer 56 in this order.

(ii) A shutter (an intermediate mask) is provided between an evaporation material reservoir and a mask so that only evaporation material ejected in a predetermined direction can be selectively utilized in evaporation. Reducing the size of the shutter opening can ensure larger anisotropy. Larger anisotropy can be attained also by ensuring larger separation (distance) between the shutter and the reservoir.

(iii)Increasing internal pressure of the evaporation material reservoir can increase the ejection speed of the evaporation material, resulting in larger anisotropy.

(iv) Larger separation between the evaporation material reservoir and the mask can attain larger anisotropy.

Using any of the above methods, anisotropy of evaporation material can be controlled to control respective film deposition areas while using the same mask.

It should be noted that the organic light emissive layer 54 and the electron transport layer 56 in FIG. 1 and the hole-transport layer 52, the organic light emissive layer 54, and the electron transport layer 56 in FIG. 2 are formed substantially rectangular so as to be arranged within a region for a single pixel. However, these layers can have other shapes such as, for example, a striped shape. In stripe formation, an upper layer is terminated on its lower layer only in the width direction, extending extends across pixels in the longitudinal direction.

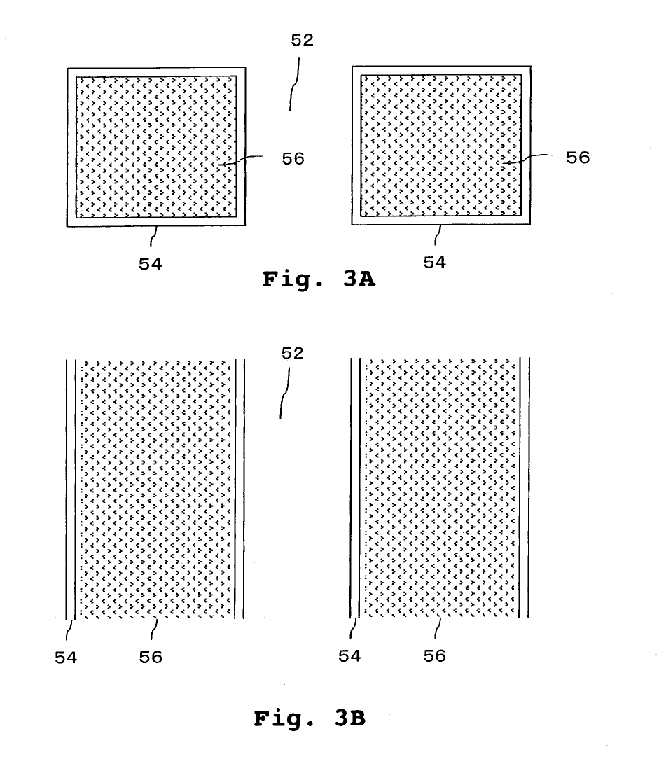

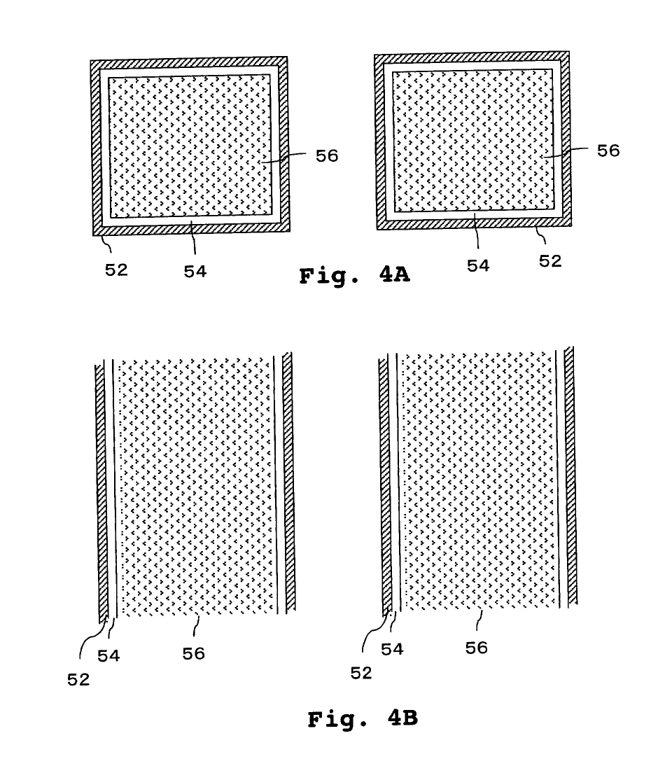

FIGS. 3A and 3B are plan views schematically showing an organic light emissive layer 54 and an electron transport layer 56 formed substantially rectangular (FIG. 3A) and those which are formed in stripe (FIG. 3B). FIGS. 4A and 4B are plan views schematically showing the hole-transport layer 52, the organic light emissive layer 54, and the electron transport layer 56 which are formed substantially rectangular (FIG. 4A) and those which are formed in stripe (FIG. 4B).

As described above, according to the present invention, the electron transport layer to be stacked on the organic emissive layer is made smaller than the organic emissive layer. This allows use of the same mask for formation of those layers, eliminating the need of exchanging evaporation masks in film formation. In addition, because upper layers are smaller than lower layers, the lateral sides of the lower layer are not covered by a thinner portion of the upper layer, and adverse effects on light emission can be prevented.

What is claimed is:

1. An organic EL panel having organic EL elements arranged in a matrix, each of the organic EL elements comprising:
a pixel electrode having a size corresponding to a size of a light emitting region in one pixel;
an opposed electrode being opposed to the pixel electrode; and
at least an organic emissive layer and an electron transport layer sandwiched between the pixel electrode and the opposed electrode,
wherein
the organic emissive layer and the electron transport layer are provided corresponding to a pixel electrode for every pixel, and
the electron transport layer is formed smaller than the organic emissive layer such that an edge of the electron transport layer terminates on the organic emissive layer.

2. An organic EL panel having organic EL elements arranged in a matrix, each of the organic EL elements comprising:
a pixel electrode having a size corresponding to a size of a light emitting region in one pixel;
an opposed electrode being opposed to the pixel electrode; and
at least a hole transport layer, an organic emissive layer, and an electron transport layer sandwiched between the pixel electrode and the opposed electrode,
wherein
the hole transport layer, the organic emissive layer, and the electron transport layer are provided corresponding to a pixel electrode for every pixel, and
the hole transport layer, the organic emissive layer, and the electron transport layer are formed with sizes decreasing in that order so that an edge of the organic emissive layer terminates on the hole transport layer and that an edge of the electron transport layer terminates on the organic emissive layer.

3. A method for manufacturing an organic EL panel having organic EL elements arranged in a matrix, wherein each of the organic EL elements comprises:
a pixel electrode having a size corresponding to a size of a light emitting region in one pixel;
an opposed electrode being opposed to the pixel electrode; and
at least an organic emissive layer and an electron transport layer sandwiched between the pixel electrode and the opposed electrode,
and wherein
the organic emissive layer and the electron transport layer are provided corresponding to a pixel electrode for every pixel, and
the electron transport layer is formed smaller than the organic emissive layer such that an edge of the electron transport layer terminates on the organic emissive layer.

4. A method for manufacturing an organic EL panel having organic EL elements arranged in a matrix, wherein each of the organic EL elements comprises:
a pixel electrode having a size corresponding to a size of a light emitting region in one pixel;
an opposed electrode being opposed to the pixel electrode; and
at least a hole transport layer, an organic emissive layer, and an electron transport layer sandwiched between the pixel electrode and the opposed electrode,
and wherein
the hole transport layer, the organic emissive layer, and the electron transport layer are provided corresponding to a pixel electrode for every pixel, and
the hole transport layer, the organic emissive layer, and the electron transport layer are formed with sizes decreasing in that order so that an edge of the organic emissive layer terminates on the hole transport layer and that an edge of the electron transport layer terminates on the organic emissive layer.

5. The method for manufacturing an organic EL panel according to claim 3, wherein the hole transport layer, the organic emissive layer, and the electron transport layer are formed using a same mask while varying anisotropy of evaporation material in evaporation to thereby control a dimension of each layer.
